(19) United States
(12) Patent Application Publication
(10) Pub. No.: US 2026/0239963 A1
(43) Pub. Date: Aug. 13, 2026

(54) CHIP STACK STRUCTURE AND SEMICONDUCTOR PACKAGE INCLUDING THE SAME

(71) Applicant: Samsung Electronics Co., Ltd., Suwon-si (KR)

(72) Inventors: Jeongeun HER, Suwon-si (KR); Jisoo KIM, Suwon-si (KR); Hojun CHOI, Suwon-si (KR); Hyunjun BAE, Suwon-si (KR); Jaeho JEON, Suwon-si (KR); KyuTae JEONG, Suwon-si (KR); Dong-Hwan HAN, Suwon-si (KR)

(21) Appl. No.: 19/278,859

(22) Filed: Jul. 24, 2025

(30) Foreign Application Priority Data
Feb. 11, 2025 (KR) 10-2025-0017287

(51) Int. Cl. H01L 23/367; H01L 21/768; H01L 23/00; H01L 23/373; H01L 23/48; H01L 23/498; H01L 23/528; H01L 25/065

(52) U.S. Cl. CPC H10W 40/228; H10W 20/20; H10W 20/43; H10W 40/25; H10W 70/69; H10W 90/00; H10W 20/056; H10W 74/10; H10W 90/288; H10W 90/297; H10W 90/722; H10W 90/724

(57) ABSTRACT

A chip stack structure includes a first semiconductor chip including a first device layer, a first wiring structure electrically connected to the first device layer, and a through-electrode electrically connected to the first wiring structure, a second semiconductor chip stacked in a first direction perpendicular to a first surface of the first semiconductor chip and facing the first surface of the first semiconductor chip, and a surface heat-dissipating layer on the first surface of the first semiconductor chip. The through-electrode extends through the first surface of the first semiconductor chip in the first direction and overlaps the surface heat-dissipating layer in a second direction perpendicular to the first direction.

### CROSS-REFERENCE TO RELATED APPLICATION

This application is based on and claims priority to Korean Patent Application No. 10-2025-0017287, filed in the Korean Intellectual Property Office on Feb. 11, 2025, the entire contents of which are hereby incorporated by reference.

### FIELD

The present disclosure relates to a chip stack structure and a semiconductor package including the same.

### BACKGROUND

Due to the reduction in weight and the increase in performance of electronic devices, there is demand in the semiconductor package field for developing miniaturized and high-performance semiconductor packages. Research and development on semiconductor packages in which a plurality of semiconductor chips are vertically stacked has been conducted to achieve miniaturization, weight reduction, high performance, and high reliability of semiconductor packages.

When a plurality of semiconductor chips are stacked, power density may increase and heat may be generated when power and signals are delivered between the stacked semiconductor chips. Since the generated heat can raise the temperature of the plurality of semiconductor chips or the semiconductor package, it may be necessary to dissipate the heat to the outside, for example, to at least one external surface of the chips or package.

### SUMMARY

Some embodiments of the present disclosure may provide a chip stack structure having improved heat dissipation performance and a semiconductor package including the same.

Further embodiments of the present disclosure may provide a chip stack structure having improved electrical performance and electrical reliability and a semiconductor package including the same.

According to some embodiments of the present disclosure, a chip stack structure may include a first semiconductor chip including a first device layer, a first wiring structure electrically connected to the first device layer, and a through-electrode electrically connected to the first wiring structure, a second semiconductor chip stacked in a first direction perpendicular to a first surface of the first semiconductor chip and the second semiconductor chip facing the first surface of the first semiconductor chip, and a surface heat-dissipating layer on the first surface of the first semiconductor chip, the through-electrode extends through the first surface of the first semiconductor chip in the first direction and overlaps the surface heat-dissipating layer in a second direction perpendicular to the first direction.

According to some embodiments of the present disclosure, a chip stack structure may include a first semiconductor chip including a first device layer, a first wiring structure electrically connected to the first device layer, and a through-electrode electrically connected to the first wiring structure, a backside pad on a back surface of the first semiconductor chip, a second semiconductor chip may include a second device layer and a second wiring structure electrically connected to the second device layer, the second semiconductor chip stacked in a first direction to face the back surface of the first semiconductor chip, a first connection terminal on the through-electrode and electrically connecting the first semiconductor chip and the second semiconductor chip, a second connection terminal on the backside pad and electrically connecting the first semiconductor chip and the second semiconductor chip, and a backside heat-dissipating layer on the back surface of the first semiconductor chip, the through-electrode extends through the back surface of the first semiconductor chip in the first direction and overlaps the backside heat-dissipating layer in a second direction perpendicular to the first direction.

According to some embodiments of the present disclosure, a semiconductor package may include a package substrate, and a chip stack structure on the package substrate, the chip stack structure may include a first semiconductor chip mounted on the package substrate, the first semiconductor chip including a first device layer, a first wiring structure electrically connected to the first device layer, and a through-electrode electrically connected to the first wiring structure, a second semiconductor chip may include a second device layer and a second wiring structure electrically connected to the second device layer, the second semiconductor chip being stacked in a first direction on a back surface of the first semiconductor chip, a first connection terminal on the through-electrode between the first semiconductor chip and the second semiconductor chip and electrically connecting the first semiconductor chip and the second semiconductor chip, a first backside insulating layer extending around the through-electrode on the back surface of the first semiconductor chip, and a backside heat-dissipating layer on the back surface of the first semiconductor chip, the backside heat-dissipating layer comprising at least one surface that is coplanar with a surface of the first backside insulating layer, the through-electrode extends through the back surface of the first semiconductor chip in the first direction and overlaps each of the first backside insulating layer and the backside heat-dissipating layer in a second direction perpendicular to the first direction.

According to some embodiments of the present disclosure, a method of manufacturing a chip stack structure may include forming a first semiconductor chip on a substrate, the first semiconductor chip including a device layer and a front wiring layer, forming a trench that penetrates part of the first semiconductor chip in a first direction, forming a through heat-dissipating layer in the trench and a backside heat-dissipating layer on a back surface of the first semiconductor chip, forming a through-electrode on the through heat-dissipating layer so as to overlap the backside heat-dissipating layer in a second direction perpendicular to the first direction, and stacking a second semiconductor chip on the back surface of the first semiconductor chip.

According to some embodiments of the present disclosure, the method of manufacturing the chip stack structure may further include replacing part of the backside heat-dissipating layer with a backside insulating layer.

According to some embodiments of the present disclosure, the replacing with the backside insulating layer may include oxidizing part of the backside heat-dissipating layer.

According to some embodiments of the present disclosure, the replacing with the backside insulating layer may include removing part of the backside heat-dissipating layer and filling with an insulating material.

According to some embodiments of the present disclosure, the method of manufacturing the chip stack structure may further include forming a backside pad on the backside insulating layer.

According to some embodiments of the present disclosure, the method of manufacturing the chip stack structure may further include forming a first connection terminal on the through-electrode and forming a second connection terminal on the backside pad, where the first connection terminal and the second connection terminal may electrically connect the first semiconductor chip and the second semiconductor chip.

According to some embodiments of the present disclosure, the backside insulating layer may include a first insulating layer on the first surface and extending around the through-electrode, where the through-electrode and the backside heat-dissipating layer are spaced apart from each other in the second direction, and a second insulating layer extending around the backside pad in a plan view.

According to some embodiments of the present disclosure, the through heat-dissipating layer may extend along a side surface and a bottom surface of the through-electrode.

According to some embodiments of the present disclosure, the backside heat-dissipating layer and the through heat-dissipating layer may include graphene.

According to some embodiments of the present disclosure, the through heat-dissipating layer may include a bent portion extending along the first surface of the first semiconductor chip from the side surface of the through-electrode, and an upper surface of the bent portion may be coplanar with an upper surface of the through-electrode.

According to some embodiments of the present disclosure, heat-dissipating performance of the chip stack structure and the semiconductor package can be improved.

According to some embodiments of the present disclosure, the electrical performance and reliability of the chip stack structure and the semiconductor package can be improved.

### BRIEF DESCRIPTION OF THE DRAWINGS

FIG. 1 is a plan view schematically illustrating a chip stack structure according to some embodiments of the present disclosure.

FIG. 2 is a cross-sectional view illustrating a semiconductor package according to some embodiments of the present disclosure.

FIGS. 3 to 5 are enlarged views of a portion of FIG. 2.

FIG. 6 is a plan view illustrating a portion of FIG. 2.

FIGS. 7 to 9 are diagrams for explaining a chip stack structure according to some embodiments of the present disclosure.

FIGS. 10 to 12 are diagrams for explaining a chip stack structure according to some embodiments of the present disclosure.

FIGS. 13 to 22 are diagrams for explaining a method of manufacturing a chip stack structure according to some embodiments of the present disclosure.

### DETAILED DESCRIPTION OF EMBODIMENTS

Hereinafter, a chip stack structure and a semiconductor package including the same according to some embodiments of the present disclosure will be described in detail with reference to the drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout.

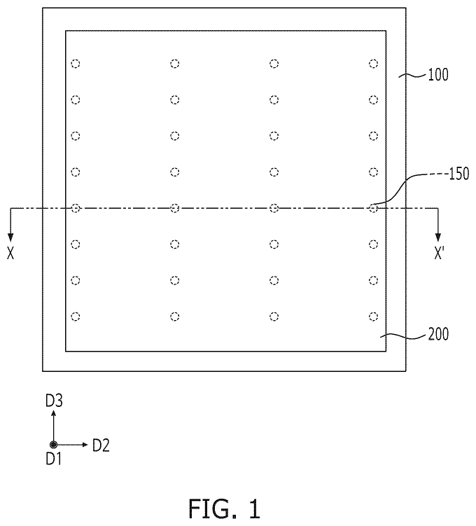

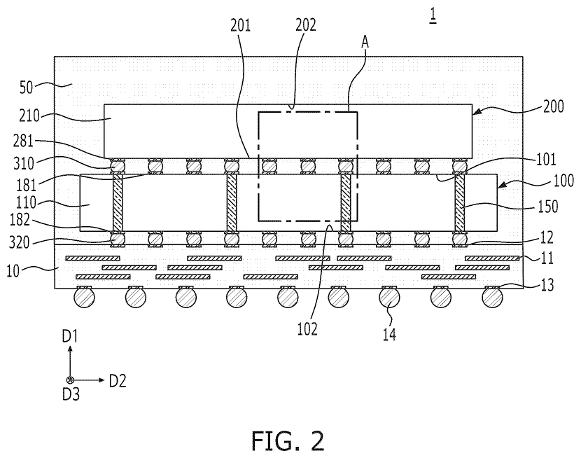

FIG. 1 is a plan view schematically illustrating a chip stack structure according to some embodiments of the present disclosure. FIG. 2 is a cross-sectional view illustrating a semiconductor package according to some embodiments of the present disclosure. FIG. 2 may correspond to a cross section taken along line X-X′ of FIG. 1.

Referring to FIGS. 1 and 2, a semiconductor package 1 according to some embodiments of the present disclosure may include a package substrate 10, a first semiconductor chip 100, a second semiconductor chip 200, connection terminals 310, connection terminals 320, and a molding layer 50.

The package substrate 10 may be a printed circuit board (PCB), a ceramic substrate, a wafer for package manufacturing, an interposer, or a redistribution layer. In some embodiments, the printed circuit board may be a multilayer printed circuit board having a substrate base in which a plurality of base layers are stacked. In some embodiments, each of the plurality of base layers forming the substrate base may include at least one material selected from phenol resin, epoxy resin, and polyimide. For example, each of the plurality of base layers forming the substrate base may include at least one material selected from FR4 (Flame Retardant 4), tetrafunctional epoxy, polyphenylene ether, epoxy/polyphenylene oxide, BT (Bismaleimidetriazine), Thermount, cyanate ester, polyimide, and liquid crystal polymer.

The package substrate 10 may include a wiring pattern 11, upper pads 12, and lower pads 13. The wiring pattern 11 may be disposed on upper and lower surfaces of each of the plurality of base layers. The wiring pattern 11 may be formed, for example, of electrolytically deposited (ED) copper foil, rolled-annealed (RA) copper foil, stainless steel foil, aluminum foil, ultra-thin copper foils, sputtered copper, copper alloys, or the like. In some embodiments, a conductive via connecting the wiring patterns 11 to each other may electrically connect the wiring patterns 11. The conductive via may be formed to penetrate at least one of the plurality of base layers. In some embodiments, the conductive via may be formed of copper, nickel, stainless steel, or beryllium copper.

The upper pads 12 may be disposed on an upper surface of the package substrate 10, and the lower pads 13 may be disposed on a lower surface of the package substrate 10. Each of the upper pads 12 and the lower pads 13 may be provided in plurality. Connection terminals 320 may be disposed on the upper pads 12. Through the upper pads 12, the first semiconductor chip 100 and the package substrate 10 may be electrically connected.

A plurality of external terminals 14 may be disposed on the plurality of lower pads 13. Through the plurality of external terminals 14, the semiconductor package 1 can be mounted on a system board. That is, the plurality of external terminals 14 can be electrically connected to pads of the system board.

The first semiconductor chip 100 may be mounted on the package substrate 10. A first surface 101 of the first semiconductor chip 100 refers to a surface facing the second semiconductor chip 200, and a second surface 102 of the first semiconductor chip 100 refers to a surface facing the package substrate 10. In some embodiments, the first surface 101 of the first semiconductor chip 100 may be a backside surface on which a backside wiring layer is formed. In other embodiments, the first surface 101 of the first semiconductor chip 100 may be a front side (or front surface) on which a device layer and a front wiring layer are formed.

The first semiconductor chip 100 may include a first substrate 110, a first pad 181, a second pad 182, and through-electrodes 150.

The first substrate 110 may include, for example, a semiconductor element such as silicon or germanium (Ge), or a compound semiconductor such as silicon carbide (SiC), gallium arsenide (GaAs), indium arsenide (InAs), or indium phosphide (InP). The first substrate 110 may have an SOI (Silicon On Insulator) structure. The first substrate 110 may include a conductive region, for example, a well doped with impurities or a structure doped with impurities. The first substrate 110 may include various device isolation structures such as shallow trench isolation (STI).

The first pad 181 may be disposed on the first surface 101 of the first semiconductor chip 100. The second pad 182 may be disposed on the second surface 102 of the first semiconductor chip 100. The first pad 181 and the second pad 182 may each be provided in plurality. The first pad 181 and the second pad 182 may each include, for example, at least one of aluminum (Al), copper (Cu), nickel (Ni), tungsten (W), platinum (Pt), and gold (Au). However, the materials of the first pad 181 and the second pad 182 are not limited thereto. In some embodiments, the first substrate 110 may be replaced with a wiring structure, etc.

A connection terminal 310 may be disposed on the first pad 181 of the first semiconductor chip 100. A connection terminal 320 may be disposed on the second pad 182 of the first semiconductor chip 100. Through the first pad 181 and the connection terminal 310, the second semiconductor chip 200 and the first semiconductor chip 100 can be electrically connected.

For example, each of the connection terminal 310 and the connection terminal 320 may include tin (Sn), indium (In), bismuth (Bi), antimony (Sb), copper (Cu), silver (Ag), zinc (Zn), lead (Pb), and/or alloys thereof. The alloys may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and so forth.

The through-electrodes 150 may connect the first pads 181 and the second pads 182. The through-electrodes 150 may be arranged in a second direction D2 and a third direction D3. The through-electrodes 150 may extend through or penetrate the first substrate 110 in a first direction D1. The through-electrodes 150 may provide an electrical path connecting the first pads 181 and the second pads 182.

The through-electrodes 150 may include a central metal layer and a barrier film surrounding it. The central metal layer may include a metal material, for example, tungsten (W), titanium (Ti), aluminum (Al), or copper (Cu). The central metal layer may be formed by a plating process, a PVD process, or a CVD process. The barrier film may include titanium (Ti), titanium nitride (TiN), tantalum (Ta), or tantalum nitride (TaN) and may be formed by a plating process, a PVD process, or a CVD process. In some embodiments, a side insulating film including an insulating material such as silicon oxide, silicon nitride, or silicon oxynitride may be formed between a side surface of each through-electrode 150 and the first substrate 110.

The first semiconductor chip 100 may be, for example, a buffer chip that includes a plurality of logic devices and/or memory devices in a device layer. The first semiconductor chip 100 may deliver a signal from the second semiconductor chip 200 stacked thereon to the outside and deliver a signal and power from the outside to the second semiconductor chip 200. While the first semiconductor chip 100 may perform both logic and memory functions through logic devices and memory devices, the first semiconductor chip 100 may include only logic devices. In some embodiments, the first semiconductor chip 100 may include a volatile memory device such as DRAM (Dynamic Random Access Memory) or SRAM (Static Random Access Memory), or a nonvolatile memory device such as flash memory.

The second semiconductor chip 200 may be disposed on the first semiconductor chip 100. The second semiconductor chip 200 may be stacked in the first direction D1 perpendicular to the first surface 101 of the first semiconductor chip 100. The second semiconductor chip 200 may face the first surface 101 of the first semiconductor chip 100. A first surface 201 of the second semiconductor chip 200 refers to a surface facing the first semiconductor chip 100, and a second surface 202 of the second semiconductor chip 200 refers to a surface opposite to the surface facing the first surface 101 of the first semiconductor chip 100. In some embodiments, the first surface 201 of the second semiconductor chip 200 may be a front side on which a device layer and a front wiring layer are formed. In other embodiments, the first surface 201 of the second semiconductor chip 200 may be a backside surface on which a backside wiring layer is formed.

The second semiconductor chip 200 may include a second substrate 210 and a pad 281. Since each of the second substrate 210 and the pad 281 has the same or similar characteristics as the first substrate 110 and the first pad 181, redundant description thereof may be omitted.

The second semiconductor chip 200 may be composed of memory chips or memory devices that store or output data based on a received address command or control command. For example, the second semiconductor chip 200 may include volatile memory devices such as DRAM or SRAM, or nonvolatile memory devices such as PRAM, MRAM, FeRAM, or RRAM. In some embodiments, the second semiconductor chip 200 may be provided as a plurality of second semiconductor chips stacked on the first semiconductor chip 100 in the first direction D1.

The molding layer 50 may cover the first semiconductor chip 100 and the second semiconductor chip 200 on the package substrate 10. For example, the molding layer 50 may cover the front surface, side surfaces, and back surface of each of the first semiconductor chip 100 and the second semiconductor chip 200. In some embodiments, the molding layer 50 may be formed so as to expose the second surface 202 of the second semiconductor chip 200. For example, the molding layer 50 may include an insulating material such as a thermosetting resin (e.g., epoxy resin) or a thermoplastic resin (e.g., polyimide). Further, the molding layer 50 may include a resin in which a reinforcing material such as an inorganic filler is included in a thermosetting resin or a thermoplastic resin. Specifically, the molding layer 50 may include ABF, FR-4, BT resin, etc. Additionally, the molding layer 50 may include a molding material such as EMC or a photosensitive material such as PIE (Photo Imageable Encapsulant).

The molding layer 50 may surround the connection terminal 320 disposed between the package substrate 10 and the first semiconductor chip 100. The molding layer 50 may surround the connection terminal 310 disposed between the first semiconductor chip 100 and the second semiconductor chip 200.

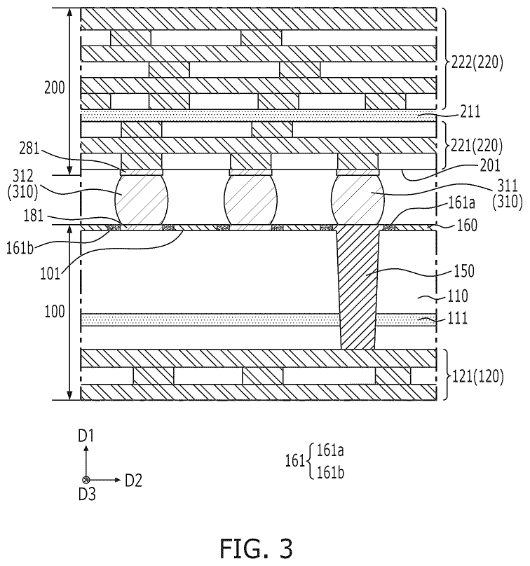

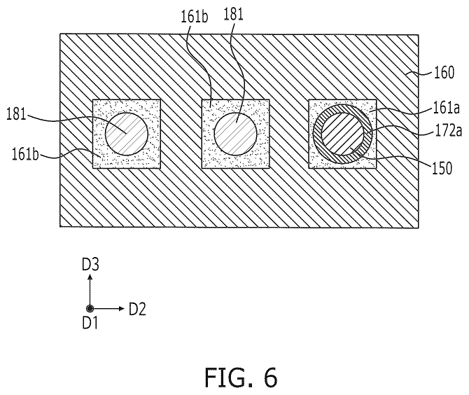

FIGS. 3 to 5 are enlarged views of a portion of FIG. 2. FIG. 6 is a plan view illustrating a portion of FIG. 2. FIGS. 3 to 5 may correspond to region A of FIG. 2.

Referring to FIGS. 3 and 6, a chip stack structure according to some embodiments of the present disclosure may include the first semiconductor chip 100, the second semiconductor chip 200, connection terminals 310, a surface heat-dissipating layer 160, and an insulating layer 161. The first semiconductor chip 100 and the second semiconductor chip 200 may be electrically connected. For example, the first semiconductor chip 100 and the second semiconductor chip 200 may exchange signals with each other through the connection terminal 310. As another example, the first semiconductor chip 100 may supply power to the second semiconductor chip 200 through the connection terminal 310.

The first semiconductor chip 100 may include a first substrate 110, a first device layer 111, a first wiring structure 120, a through-electrode 150, and a first pad 181.

The first device layer 111 may be formed on the first substrate 110. The first device layer 111 may be disposed on a lower surface of the first substrate 110. That is, in the first semiconductor chip 100, the second surface thereof located below the lower surface of the first substrate 110 may be a front surface of the first semiconductor chip 100. In the first semiconductor chip 100, the upper surface of the first substrate 110 may be the first surface 101 and thus serve as a backside surface of the first semiconductor chip 100.

The first device layer 111 may include various types of devices. For example, the first device layer 111 may include field effect transistors (FETs) such as planar FETs, FinFETs, or GAAFETs, flash memory, DRAM (Dynamic Random Access Memory), SRAM (Static Random Access Memory), EEPROM (Electrically Erasable Programmable Read-Only Memory), PRAM (Phase-change Random Access Memory), MRAM (Magnetoresistive Random Access Memory), FeRAM (Ferroelectric Random Access Memory), RRAM (Resistive Random Access Memory), logic devices such as AND, OR, and NOT, system LSIs (Large Scale Integration), CIS (CMOS Image Sensors), MEMS (Micro-Electro-Mechanical Systems), and various active and/or passive devices.

The first wiring structure 120 may be electrically connected to the first device layer 111. The first wiring structure 120 may provide signal lines or power lines for various devices of the first device layer 111.

The first wiring structure 120 may include a front wiring layer 121 disposed adjacent to the front surface of the first semiconductor chip 100. The front wiring layer 121 may have a multilayer structure. The front wiring layer 121 may include a plurality of interlayer insulating films, a plurality of front wiring patterns, and a plurality of front via patterns. The number of layers, number of patterns, and arrangement of the plurality of front wiring patterns and the plurality of front via patterns are merely illustrative and are not limited to what is depicted.

The through-electrode 150 may extend through or penetrate at least part of the first semiconductor chip 100. The through-electrode 150 may extend through or penetrate the first semiconductor chip 100 in the first direction D1. For example, the through-electrode 150 may extend through or penetrate the first substrate 110 in the first direction D1. The through-electrode 150 may extend through or penetrate the first surface 101 of the first semiconductor chip 100 and the first device layer 111 in the first direction D1. For example, a lower surface of the through-electrode 150 may contact the front wiring layer 121. In some embodiments, the lower surface of the through-electrode 150 may contact one or more of the plurality of front wiring patterns included in the front wiring layer 121.

The first pad 181 may be disposed on the first surface 101 of the first semiconductor chip 100. The first pad 181 may be formed on part of the first surface 101 of the first semiconductor chip 100. The first pad 181 may overlap the through-electrode 150 in the second direction D2. The first pad 181 may be spaced apart from the through-electrode 150 in the second direction D2. In some embodiments, the upper surface of the first pad 181 may be positioned at substantially the same level as the upper surface of the through-electrode 150.

The second semiconductor chip 200 may include a second device layer 211, a second wiring structure 220, and a pad 281. Since the second device layer 211 has the same or similar characteristics as the first device layer 111, the redundant description thereof may be omitted.

The second wiring structure 220 may include a front wiring layer 221 and a back wiring layer 222. The second device layer 211 may be disposed between the front wiring layer 221 and the back wiring layer 222. For example, the front wiring layer 221 may be disposed adjacent to the first surface 201 of the second semiconductor chip 200, and the back wiring layer 222 may be disposed adjacent to the second surface 202 of the second semiconductor chip 200. The front wiring layer 221 and the back wiring layer 222 may be referred to as a first wiring layer and a second wiring layer of the second wiring structure 220, respectively.

The second wiring structure 220 may be electrically connected to the second device layer 211. The second wiring structure 220 may provide signal lines or power lines for various devices of the second device layer 211. For example, the front wiring layer 221 may provide a signal transmission path for the second device layer 211, and the back wiring layer 222 may provide a path for supplying power to the second device layer 211. That is, the second semiconductor chip 200 may be a BSPDN (Back Side Power Delivery Network) type in which the wiring for power supply is disposed on the backside of the semiconductor chip.

The front wiring layer 221 and the back wiring layer 222 may each have a multilayer structure. The description of the front wiring layer 221 and the back wiring layer 222 may be the same as the description of the front wiring layer 121 of the first wiring structure 120.

The pad 281 may be disposed on the first surface 201 of the second semiconductor chip 200. The pad 281 may be protruded from the first surface 201 of the second semiconductor chip 200, but is not limited thereto. The pad 281 may contact the front wiring layer 221. Through the front wiring layer 221, the second device layer 211 and the back wiring layer 222 may be electrically connected to the pad 281.

The connection terminal 310 may include a first connection terminal 311 and a second connection terminal 312. The first connection terminal 311 may be disposed on the through-electrode 150, and the second connection terminal 312 may be disposed on each of the first pad 181 of the first semiconductor chip 100 and the pad 281 of the second semiconductor chip 200. That is, the second connection terminal 312 may contact both the first pad 181 of the first semiconductor chip 100 and the pad 281 of the second semiconductor chip 200.

The first connection terminal 311 may be electrically connected to the through-electrode 150. In some embodiments, a pad for attaching the first connection terminal 311 may be formed on the through-electrode 150.

Through the through-electrode 150, the first connection terminal 311 may be connected to the first device layer 111 and the front wiring layer 121 of the first semiconductor chip 100. Further, the first connection terminal 311 and the second connection terminal 312 may be connected through the pad 281 to the second device layer 211, the front wiring layer 221, and the back wiring layer 222 of the second semiconductor chip 200. In some embodiments, the first connection terminal 311 may be disposed on the upper surface of both the through-electrode 150 and a through heat-dissipating layer 172.

The surface heat-dissipating layer 160 may be disposed on at least part of the first surface 101 of the first semiconductor chip 100. The surface heat-dissipating layer 160 may be formed on the portion of the first surface 101 of the first semiconductor chip 100 on which the first pad 181 is not formed. In an embodiment in which the first surface 101 of the first semiconductor chip 100 is a back surface, the surface heat-dissipating layer 160 may be referred to as a backside heat-dissipating layer. That is, the surface heat-dissipating layer 160 may overlap the first pad 181 in the second direction D2. The upper surface of the surface heat-dissipating layer 160 may be coplanar with the upper surface of the first pad 181.

The surface heat-dissipating layer 160 may overlap the through-electrode 150 in the second direction D2. At least part of the through-electrode 150 may be positioned at a level higher than the first surface 101 of the first semiconductor chip 100. The through-electrode 150 may overlap the surface heat-dissipating layer 160 in the second direction D2. For example, the upper portion of the through-electrode 150 may overlap the surface heat-dissipating layer 160 in the second direction D2. In some embodiments, the upper surface of the surface heat-dissipating layer 160 may be coplanar with the upper surface of the through-electrode 150.

The surface heat-dissipating layer 160 may provide a path for dissipating heat generated from the first semiconductor chip 100 or the second semiconductor chip 200. For example, heat generated from the first semiconductor chip 100 may be dissipated along the surface heat-dissipating layer 160 via the through-electrode 150 or the first substrate 110. Heat generated from the second semiconductor chip 200 may be dissipated along the surface heat-dissipating layer 160 via the connection terminal 310.

The surface heat-dissipating layer 160 may include a material having high electrical conductivity. The surface heat-dissipating layer 160 may be electrically connected to the through-electrode 150. The surface heat-dissipating layer 160 may include a conductive material. Additionally, the surface heat-dissipating layer 160 may include a material having high thermal conductivity. For example, the surface heat-dissipating layer 160 may include graphene.

The insulating layer 161 may include a first insulating layer 161a and a second insulating layer 161b. The first insulating layer 161a and the second insulating layer 161b may be disposed on the first surface 101 of the first semiconductor chip 100. In an embodiment in which the first surface 101 of the first semiconductor chip 100 is a backside surface, the first insulating layer 161a and the second insulating layer 161b may each be referred to as a first backside insulating layer and a second backside insulating layer.

The first insulating layer 161a may be disposed around the through-electrode 150. The first insulating layer 161a may prevent conduction between the through-electrode 150 and the surface heat-dissipating layer 160. The first insulating layer 161a may be disposed so that the through-electrode 150 and the surface heat-dissipating layer 160 are spaced from each other in the second direction D2. The first insulating layer 161a may surround the through-electrode 150 so that the through-electrode 150 and the surface heat-dissipating layer 160 are spaced apart in the second direction D2. The upper surface of the first insulating layer 161a may be coplanar with the upper surfaces of the surface heat-dissipating layer 160 and the through-electrode 150. For example, the first insulating layer 161a may overlap the through-electrode 150 and the surface heat-dissipating layer 160 in the second direction D2.

The insulating layer 161 may include an insulating material. The insulating layer 161 may include an oxide formed by oxidizing a conductive material. For example, the insulating layer 161 may include graphene oxide or the like. In some embodiments, the insulating layer 161 may include silicon oxide, silicon nitride, silicon oxynitride, and so forth.

Referring to FIG. 6, the second insulating layer 161b may be disposed around the first pad 181. The second insulating layer 161b may prevent conduction between the first pad 181 and the surface heat-dissipating layer 160. The second insulating layer 161b may be disposed so that the first pad 181 and the surface heat-dissipating layer 160 are spaced apart from each other in the second direction D2. The second insulating layer 161b may surround the first pad 181 so that the first pad 181 and the surface heat-dissipating layer 160 are spaced apart from each other in the second direction D2. The second insulating layer 161b, the first pad 181, and the surface heat-dissipating layer 160 may be coplanar. For example, the second insulating layer 161b may overlap the first pad 181 and the surface heat-dissipating layer 160 in the second direction D2.

Hereinafter, a chip stack structure according to other embodiments, different from the chip stack structure of FIG. 3, will be described. The same reference numerals are given to the same configurations as those in FIG. 3, and detailed descriptions thereof may be omitted.

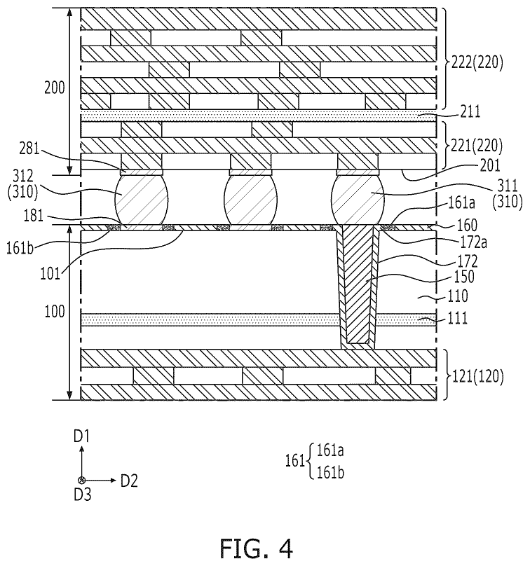

Referring to FIGS. 4 and 6, a chip stack structure according to some embodiments of the present disclosure may further include a through heat-dissipating layer 172.

The through heat-dissipating layer 172 may contact the through-electrode 150. The through heat-dissipating layer 172 may extend along a side surface and a bottom surface of the through-electrode 150. For example, the through heat-dissipating layer 172 may have a cup shape surrounding the through-electrode 150. The through heat-dissipating layer 172 may include a first portion extending along the side surface of the through-electrode 150 and a second portion extending along a back surface 101 of the first semiconductor chip 100. An inner circumferential surface of the second portion may contact the through-electrode 150. An outer circumferential surface of the second portion may contact the first backside insulating layer 161a. In some embodiments, the through heat-dissipating layer 172 may not be disposed on the bottom surface of the through-electrode 150.

The through heat-dissipating layer 172 may be disposed between the through-electrode 150 and the first substrate 110. The through heat-dissipating layer 172 may extend through or penetrate the first substrate 110 and the first device layer 111 in the first direction D1. A lower surface of the through heat-dissipating layer 172 may contact the front wiring layer 121.

The through heat-dissipating layer 172 may function as a barrier layer that prevents a metal material constituting the through-electrode 150 from diffusing. For example, it may prevent copper ions constituting the through-electrode 150 from diffusing into the interior of the first substrate 110.

The through heat-dissipating layer 172 may provide a path for dissipating heat generated in the first semiconductor chip 100. For example, heat generated in the first device layer 111 and the front wiring layer 121 may be delivered to the surface heat-dissipating layer 160 through the through heat-dissipating layer 172 or the through-electrode 150. That is, heat generated in the first semiconductor chip 100 may be dissipated through the surface heat-dissipating layer 160 via the through heat-dissipating layer 172. Heat generated in the second semiconductor chip 200 may be dissipated along the surface heat-dissipating layer 160 via the connection terminal 310.

The through heat-dissipating layer 172 may include a material having high thermal conductivity. The through heat-dissipating layer 172 may include the same material as the surface heat-dissipating layer 160. For example, the through heat-dissipating layer 172 may include at least one of graphene, DLC (Diamond Like Carbon), hBN (hexagonal Boron Nitride), or TMD (Transition Metal Dichalcogenides). However, the material constituting the through heat-dissipating layer 172 is not limited thereto. In some embodiments, the through heat-dissipating layer 172 may include a material different from that of the surface heat-dissipating layer 160.

The through heat-dissipating layer 172 may include a material having high electrical conductivity. Through the through heat-dissipating layer 172, the front wiring layer 121 and the through-electrode 150 may be electrically connected to each other. The through-electrode 150 and the through heat-dissipating layer 172 may provide a path for electrically connecting the first semiconductor chip 100 and the second semiconductor chip 200 to each other. Thus, the through heat-dissipating layer 172 may include a material having both high thermal conductivity and high electrical conductivity.

In some embodiments, the through heat-dissipating layer 172 may include an insulating material. The through heat-dissipating layer 172 may prevent conduction between the through-electrode 150 and the first substrate 110. That is, the through heat-dissipating layer 172 may include an insulating material having high thermal conductivity.

The through heat-dissipating layer 172 may include a bent portion 172a extending or bent along the first surface 101 of the first semiconductor chip 100 from the side surface of the through-electrode 150. The bent portion 172a may extend away from the through-electrode 150. An upper surface of the bent portion 172a may be coplanar with an upper surface of the through-electrode 150. The upper surface of the bent portion 172a may be positioned at substantially the same level as the upper surface of the through-electrode 150. Further, the bent portion 172a may form substantially the same plane as the surface heat-dissipating layer 160. In some embodiments, the through heat-dissipating layer 172 may not include the bent portion 172a.

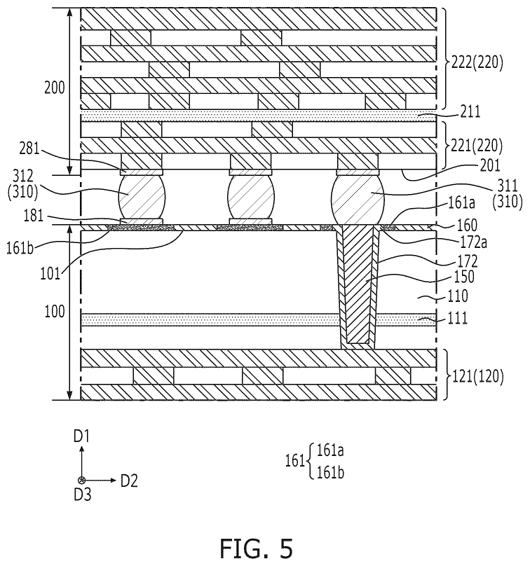

Referring to FIGS. 5 and 6, in a chip stack structure according to some embodiments of the present disclosure, the arrangement of the second insulating layer 161b and the first pad 181 may be different from the embodiments of FIGS. 3 and 4.

The second insulating layer 161b may be disposed on the first surface 101 of the first semiconductor chip 100. The second insulating layer 161b may be disposed on a portion of the first surface 101 of the first semiconductor chip 100 on which the surface heat-dissipating layer 160 is not disposed. The second insulating layer 161b may form substantially the same plane as (i.e., may be coplanar with) the surface heat-dissipating layer 160. In some embodiments, the thickness of the second insulating layer 161b may differ from that of the surface heat-dissipating layer 160.

The first pad 181 may be disposed on the second insulating layer 161b. That is, a lower surface of the first pad 181 may contact the upper surface of the second insulating layer 161b. The first pad 181 may be formed on the second insulating layer 161b. When the first pad 181 is formed by high-temperature heat treatment, part of the second insulating layer 161b may melt and combine.

The second insulating layer 161b may be disposed so that the first pad 181 is spaced apart in the second direction D2 from the surface heat-dissipating layer 160. An area of the first pad 181 may be smaller than an area of the second insulating layer 161b. Referring to FIG. 6, in a plan view, the first pad 181 may be located within the second insulating layer 161b.

In some embodiments, a height of the second connection terminal 312 in the first direction D1 may be smaller than a height of the first connection terminal 311 in the first direction D1.

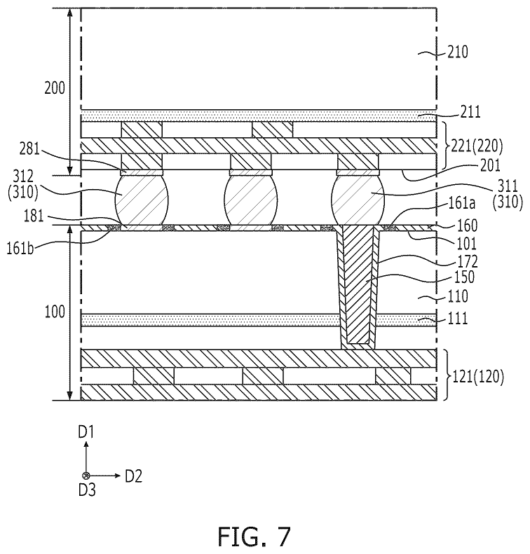

FIGS. 7 to 9 are diagrams for explaining a chip stack structure according to some embodiments of the present disclosure.

Referring to FIG. 7, in a chip stack structure according to some embodiments of the present disclosure, the structure of the second semiconductor chip 200 may differ from the embodiment of FIG. 4.

The second semiconductor chip 200 may include a second substrate 210, a second device layer 211, and a second wiring structure 220.

The second wiring structure 220 may include a front wiring layer 221 and may not include a back wiring layer. For example, the front wiring layer 221 may be disposed adjacent to the first surface 201 of the second semiconductor chip 200. The front wiring layer 221 may be disposed on a lower surface of the second device layer 211.

The second wiring structure 220 may be electrically connected to the second device layer 211. The second wiring structure 220 may provide signal lines or power lines for various devices of the second device layer 211. For example, the front wiring layer 221 may provide a signal transmission path for the second device layer 211. That is, the second semiconductor chip 200 may be an FSPDN (Front Side Power Delivery Network) type in which wiring for signals and power supply is disposed on the front side of the semiconductor chip.

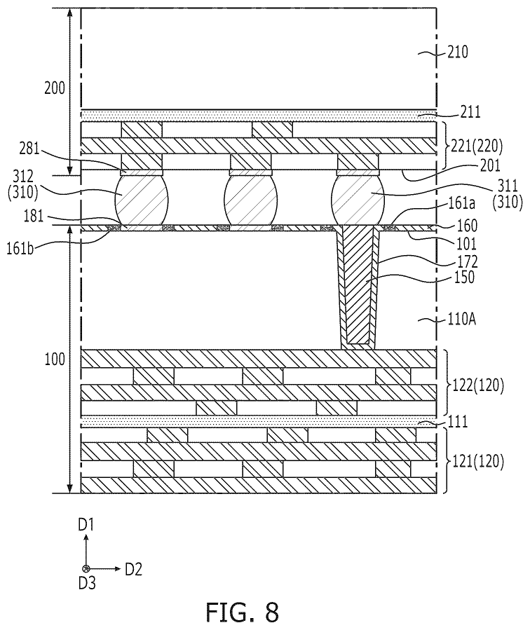

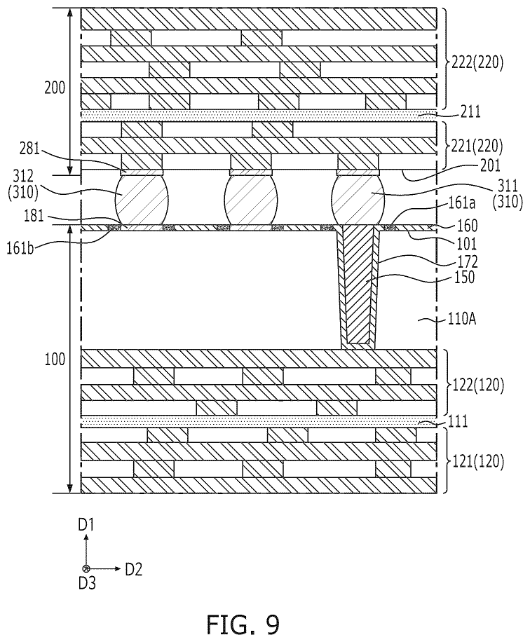

Referring to FIGS. 8 and 9, in a chip stack structure according to some embodiments of the present disclosure, the structure of the first semiconductor chip 100 may differ from the embodiments of FIGS. 4 and 7, respectively.

The first semiconductor chip 100 may include a support substrate 110A, a first device layer 111, a first wiring structure 120, and a through-electrode 150.

The support substrate 110A may form the front surface of the first semiconductor chip 100. That is, an upper surface of the support substrate 110A may be the first surface 101 of the first semiconductor chip 100. The support substrate 110A may be bulk silicon or SOI (silicon-on-insulator). Alternatively, the substrate SUB may include silicon germanium (SiGe), SGOI (silicon germanium on insulator), indium antimonide, lead tellurium compounds, indium arsenide, indium phosphide, gallium arsenide, or gallium antimonide, but is not limited thereto.

The support substrate 110A may be disposed on an upper surface of the first wiring structure 120. For example, the support substrate 110A may be disposed on an upper side of a back wiring layer 122.

The first wiring structure 120 may be electrically connected to the first device layer 111. The first wiring structure 120 may provide signal lines or power lines for various devices of the first device layer 111.

The first wiring structure 120 may include a front wiring layer 121 and a back wiring layer 122. That is, the first semiconductor chip 100 may be a BSPDN (Back Side Power Delivery Network) type in which the wiring for supplying power is disposed on the back side of the semiconductor chip.

The first device layer 111 may be disposed between the front wiring layer 121 and the back wiring layer 122. For example, the front wiring layer 121 may be disposed adjacent to the second surface of the first semiconductor chip 100, and the back wiring layer 122 may be disposed adjacent to the first surface 101 of the first semiconductor chip 100. The front wiring layer 121 and the back wiring layer 122 may each be referred to as a first wiring layer and a second wiring layer of the first wiring structure 120, respectively.

The through-electrode 150 and a through heat-dissipating layer 172 may extend through or penetrate the support substrate 110A in the first direction D1. The through-electrode 150 and the through heat-dissipating layer 172 may extend through or penetrate the first surface 101 of the first semiconductor chip 100 in the first direction D1. For example, a lower surface of the through heat-dissipating layer 172 may contact the back wiring layer 122. In some embodiments, a chip stack structure may not include the through heat-dissipating layer 172, and a lower surface of the through-electrode 150 may contact the back wiring layer 122.

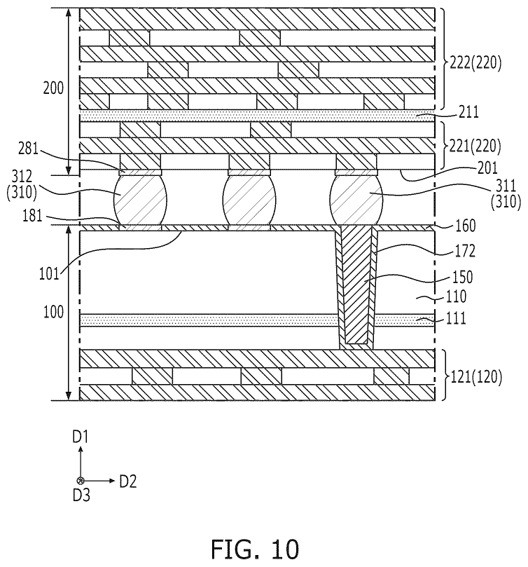

FIGS. 10 to 12 are diagrams for explaining a chip stack structure according to some embodiments of the present disclosure.

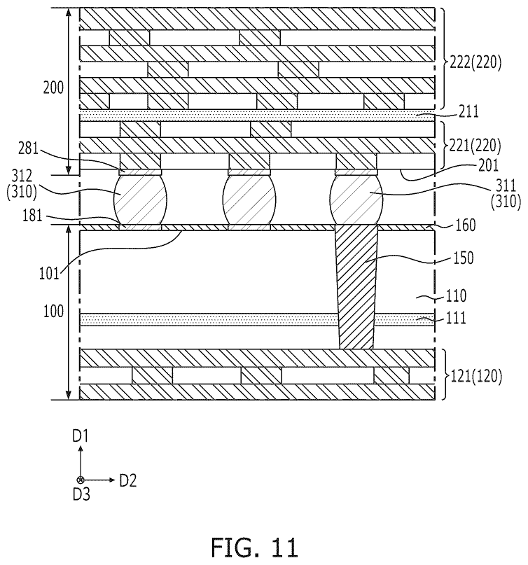

Referring to FIGS. 10 and 11, in a chip stack structure according to some embodiments of the present disclosure, the insulating layer 161 may not be included. The surface heat-dissipating layer 160 and the through heat-dissipating layer 172 may include an insulating material having high thermal conductivity. For example, the surface heat-dissipating layer 160 and the through heat-dissipating layer 172 may include at least one of DLC (Diamond Like Carbon), hBN (hexagonal Boron Nitride), or TMD (Transition Metal Dichalcogenides). For example, the TMD may include MoS2, WS2, HfS2, ZrS2, etc. However, the material constituting the surface heat-dissipating layer 160 is not limited thereto.

The surface heat-dissipating layer 160 may be disposed on the first surface 101 of the first semiconductor chip 100. An upper surface of the surface heat-dissipating layer 160 may be coplanar with an upper surface of the through-electrode 150.

A part of the surface heat-dissipating layer 160 may have the first pad 181 disposed thereon. The surface heat-dissipating layer 160 may be disposed around the first pad 181. The first pad 181 and the surface heat-dissipating layer 160 may form substantially the same plane. As the first pad 181 is formed by high-temperature heat treatment, part of the surface heat-dissipating layer 160 may melt and combine. In some embodiments, the thickness of the first pad 181 may differ from that of the surface heat-dissipating layer 160.

Referring to FIG. 10, heat generated in the first semiconductor chip 100 may be delivered to the surface heat-dissipating layer 160 via the through heat-dissipating layer 172 and the through-electrode 150. Referring to FIG. 11, heat generated in the first semiconductor chip 100 may be delivered to the surface heat-dissipating layer 160 via the through-electrode 150. In this manner, the heat generated in the first semiconductor chip 100 may be delivered along the surface heat-dissipating layer 160 and dissipated to the outside, i.e., external to the first chip 100.

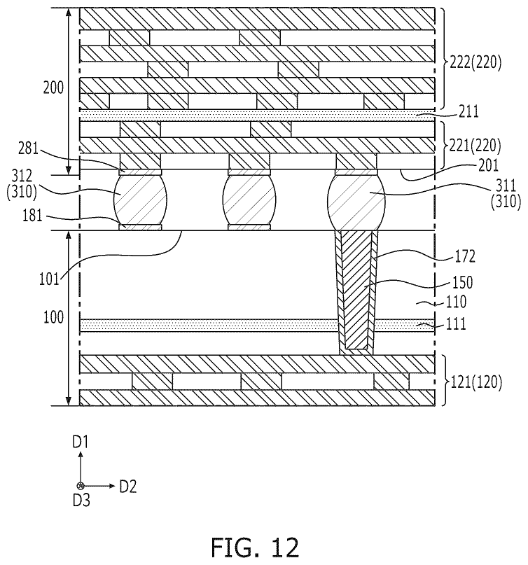

Referring to FIG. 12, in a chip stack structure according to some embodiments of the present disclosure, the surface heat-dissipating layer may not be included, and the through heat-dissipating layer 172 may be included. The through heat-dissipating layer 172 may include a material having high thermal conductivity. For example, the through heat-dissipating layer 172 may include a conductive material having high thermal conductivity or an insulating material having high thermal conductivity.

The surface heat-dissipating layer 160 may not be disposed on the first surface 101 of the first semiconductor chip 100. The first pad 181 may be disposed on the first surface 101 of the first semiconductor chip 100.

The first surface 101 of the first semiconductor chip 100 and the upper surfaces of the through-electrode 150 and the through heat-dissipating layer 172 may be coplanar or may form substantially the same plane. The first surface 101 of the first semiconductor chip 100 and the upper surfaces of the through-electrode 150 and the through heat-dissipating layer 172 may be positioned at the same level.

Heat generated in the first semiconductor chip 100 may be delivered to the first substrate 110 via the through heat-dissipating layer 172. That is, the heat may be dissipated to the outside through the through heat-dissipating layer 172 and the first substrate 110.

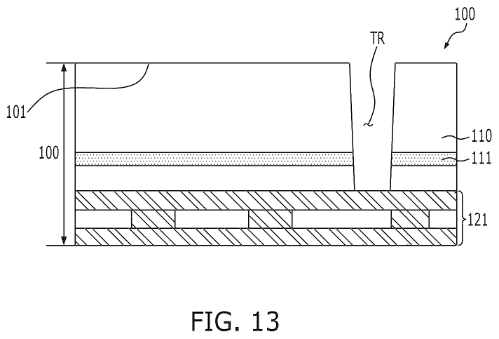

FIGS. 13 to 22 are diagrams for explaining a method of manufacturing a chip stack structure according to some embodiments of the present disclosure.

FIGS. 13 to 18 are diagrams for explaining a method of forming a surface heat-dissipating layer 160 and a through heat-dissipating layer 172 in a first semiconductor chip 100 that does not include a back wiring layer.

Referring to FIG. 13, a first semiconductor chip 100 including a device layer 111 and a front wiring layer 121 may be formed on a substrate 110. Then, a trench TR that penetrates part of the first semiconductor chip 100 in a first direction D1 may be formed.

The trench TR may be formed to create a through-electrode or a through heat-dissipating layer. The trench TR may be formed by penetrating the first substrate 110 and the first device layer 111. The trench TR may be formed by an etching process. For example, the trench TR may be formed by a wet etching or dry etching process. By the etching process, part of the first substrate 110 and the first device layer 111 may be removed.

The trench TR may be formed so as to reach the upper surface of the front wiring layer 121. Through the trench TR, part of the front wiring layer 121 may be exposed. In some embodiments, the trench TR may be formed so as to penetrate at least one of the plurality of wiring patterns forming the front wiring layer 121.

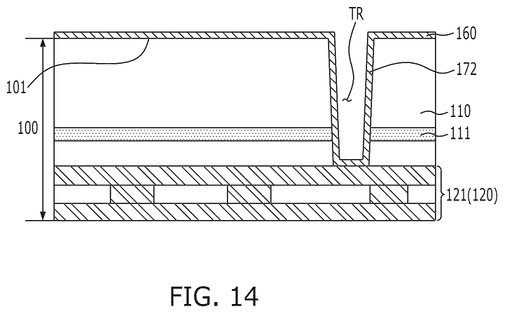

Referring to FIG. 14, the surface heat-dissipating layer 160 may be formed on the first surface 101 of the first semiconductor chip 100, and the through heat-dissipating layer 172 may be formed inside the trench TR.

The surface heat-dissipating layer 160 and the through heat-dissipating layer 172 may be integrally formed, that is, as a continuous layer free of interfaces therebetween, in some embodiments. The surface heat-dissipating layer 160 and the through heat-dissipating layer 172 may include a conductive material. In addition, the surface heat-dissipating layer 160 and the through heat-dissipating layer 172 may be formed of graphene. For example, the surface heat-dissipating layer 160 and the through heat-dissipating layer 172 may be formed of single-layer or multi-layer graphene. The surface heat-dissipating layer 160 and the through heat-dissipating layer 172 may be conformally formed by a CVD (Chemical Vapor Deposition) process. Or, the surface heat-dissipating layer 160 and the through heat-dissipating layer 172 may be formed by sputtering and PVD (Physical Vapor Deposition). In some embodiments, while the surface heat-dissipating layer 160 and the through heat-dissipating layer 172 are formed of the same material, they may be formed by different processes.

The trench TR may have a shape recessed from the first surface 101 of the first semiconductor chip. In some embodiments, the surface heat-dissipating layer 160 and the through heat-dissipating layer 172 may each include a portion extending along the shape recessed from the first surface 101 of the first semiconductor chip.

In some embodiments, the surface heat-dissipating layer 160 and the through heat-dissipating layer 172 may be formed of different materials. Both the surface heat-dissipating layer 160 and the through heat-dissipating layer 172 may include materials having high thermal conductivity. However, the through heat-dissipating layer 172 may be formed of an insulating material, and the surface heat-dissipating layer 160 may be formed of a conductive material. For example, the through heat-dissipating layer 172 may be formed of hBN, and the surface heat-dissipating layer 160 may be formed of graphene.

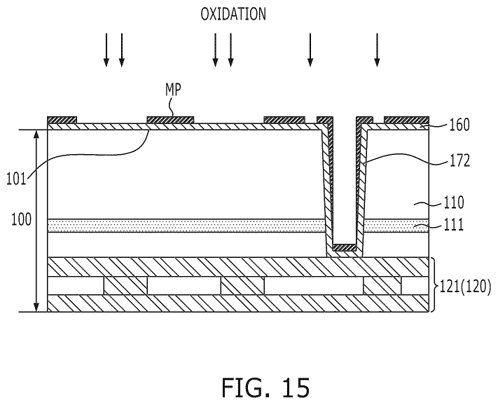

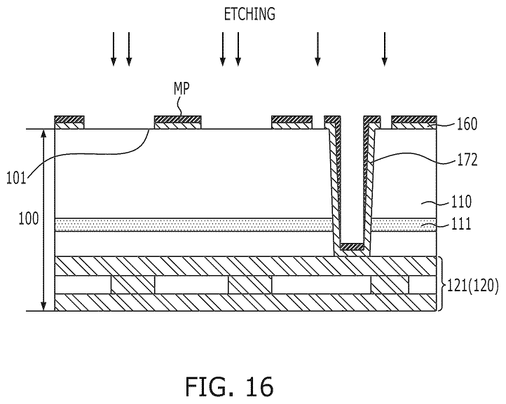

Referring to FIG. 15 or FIG. 16, a mask pattern MP may be disposed on the surface heat-dissipating layer 160 and the through heat-dissipating layer 172. For example, part of the surface heat-dissipating layer 160 may be covered by the mask pattern MP, and the entire through heat-dissipating layer 172 may be covered. The mask pattern MP may expose a portion where the first insulating layer and the second insulating layer are to be formed on the surface heat-dissipating layer 160.

In some embodiments, the mask pattern MP may be disposed on the bent sections of the surface heat-dissipating layer 160 and the through heat-dissipating layer 172. The mask pattern MP may cover the bent sections of the surface heat-dissipating layer 160 and the through heat-dissipating layer 172. That is, the bent sections of the surface heat-dissipating layer 160 and the through heat-dissipating layer 172 may not be oxidized or removed.

Referring to FIG. 15, an oxidation process may be performed on the part of the surface heat-dissipating layer 160 exposed by the mask pattern MP. For example, the part may be oxidized by supplying an oxidizing agent for chemical oxidation, or by irradiating the surface with a laser or an electron beam (e-beam). In some embodiments, plasma treatment may be employed to oxidize the exposed portion of the surface heat-dissipating layer 160. In another embodiment, an oxidation reaction may be induced by applying a voltage to the surface of the surface heat-dissipating layer 160.

In this way, an oxide formed by oxidizing the conductive material constituting the surface heat-dissipating layer 160 may be produced.

Alternatively, referring to FIG. 16, an etching process may be performed on the part of the surface heat-dissipating layer 160 exposed by the mask pattern MP. For example, the exposed part may be removed using plasma, a laser, and so forth. A groove may be formed by removing the exposed portion of the surface heat-dissipating layer 160.

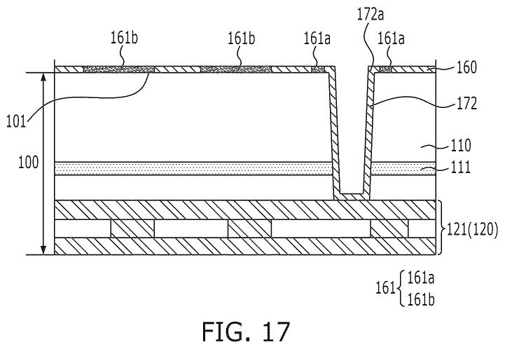

Referring to FIG. 17, the insulating layer 161 may be formed on the first surface 101 of the first semiconductor chip 100. For example, part of the backside heat-dissipating layer 160 may be formed with the insulating layer 161. Specifically, the first insulating layer 161a may be formed around the position where the through-electrode is to be formed, and a second insulating layer 161b may be formed at a position where the first pad is to be formed. In some embodiments, the first insulating layer 161a may be formed around the bent portion 172a of the through heat-dissipating layer 172.

By the oxidation process of FIG. 15, the insulating layer 161 may be formed by oxidizing part of the surface heat-dissipating layer 160. When the insulating layer 161 is formed, the first insulating layer 161a and the second insulating layer 161b may include an oxide of the conductive material. Accordingly, the oxide constituting the first insulating layer 161a and the second insulating layer 161b may have insulating properties. For example, the insulating layer 161 may include graphene oxide obtained by oxidizing graphene.

Alternatively, an insulating material may be filled into the grooves formed by removing part of the surface heat-dissipating layer 160 through the etching process of FIG. 16. The insulating layer 161 may be formed by removing part of the surface heat-dissipating layer 160 and filling with an insulating material. That is, the first insulating layer 161a and the second insulating layer 161b may be formed by filling with an insulating material. For example, the insulating layer 161 may include an insulating material such as silicon oxide, silicon nitride, silicon oxynitride, and so on.

Additionally, a conductive material may be filled into the trench to form the through-electrode. The conductive material may include copper (Cu), tungsten (W), polysilicon, aluminum (Al), and the like.

For example, a seed layer may be formed inside the trench. An electroplating process may be performed using the seed layer as an electrode. The conductive material may be filled by the electroplating process. The conductive material may be formed inside the trench so as to cover the seed layer. In some embodiments, a planarization process may be performed on the upper surface of the conductive material.

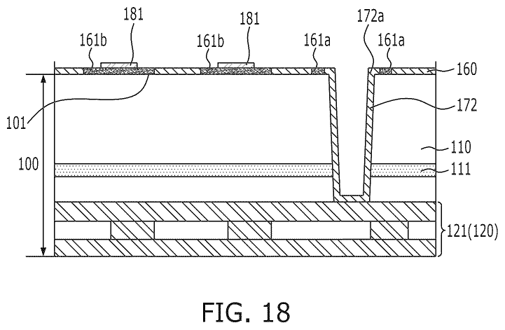

Referring to FIG. 18, the first pad 181 may be formed on the second insulating layer 161b. The first pad 181 may be formed by depositing a metal material on the second insulating layer 161b. A lower surface of the first pad 181 may contact an upper surface of the second insulating layer 161b. Additionally, a pad for attaching a first connection terminal may be formed on the through-electrode.

In some embodiments, as the first pad 181 is deposited, part of the second insulating layer 161b may melt. The second insulating layer 161b may melt and combine with the first pad 181. As the second insulating layer 161b melts, the first pad 181 may be formed to lie substantially in the same plane as (i.e., coplanar with) the second insulating layer 161b.

In some embodiments, a seed layer may be conformally disposed under the first pad 181, and an electroplating process using the seed layer as an electrode may be performed to form the first pad 181.

Subsequently, a second connection terminal may be attached on the first pad 181. A step of stacking the second semiconductor chip on the back surface of the first semiconductor chip may be performed. As the second semiconductor chip is stacked on the first semiconductor chip, the second connection terminal may be fused with a connection terminal (for example, a solder ball) attached on the second semiconductor chip by a reflow process.

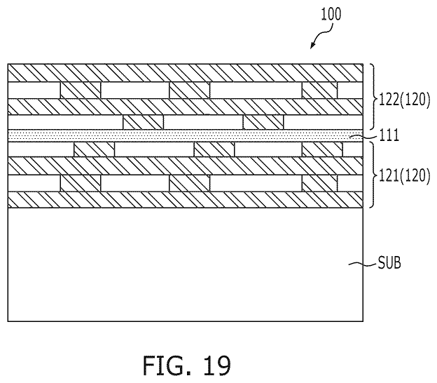

FIGS. 19 to 22 are diagrams for explaining a method of forming the surface heat-dissipating layer 160 and the through heat-dissipating layer 172 in a first semiconductor chip 100 that includes both a front wiring layer and a back wiring layer. For convenience of explanation, detailed descriptions of parts overlapping with FIGS. 13 to 18 may be omitted.

Referring to FIG. 19, a first device layer 111 and a front wiring layer 121 may be formed in the first semiconductor chip 100. The front wiring layer 121 may be formed on a front side of the first semiconductor chip 100. The front wiring layer 121 may be a signal line for the first device layer 111.

Then, a front substrate SUB may be bonded on the front wiring layer 121. The first semiconductor chip 100 may be flipped so that the front substrate SUB faces downward to form a back wiring layer 122 on the back side of the first semiconductor chip 100. Specifically, a back substrate opposite the front substrate SUB may be removed, and a plurality of interlayer insulating films, a plurality of back wiring patterns, and a plurality of back via patterns may be formed. The plurality of back wiring layers 122 may be power lines for the first device layer 111. However, the present disclosure is not limited thereto, and the front wiring layer 121 may be a power line, while the back wiring layer 122 may be a signal line.

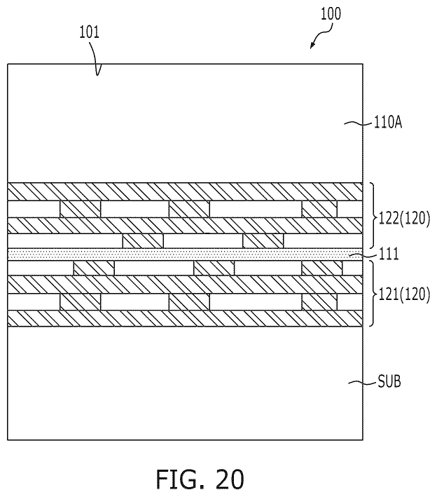

Referring to FIG. 20, a support substrate 110A may be formed on the back wiring layer 122. One surface of the support substrate 110A may contact the back wiring layer 122. The other surface of the support substrate 110A may form the first surface 101 of the first semiconductor chip 100. An oxide film for bonding may be formed between the support substrate 110A and the back wiring layer 122. For example, a silicon oxide may be interposed between the support substrate 110A and the back wiring layer 122. The support substrate 110A may be attached by the oxide film.

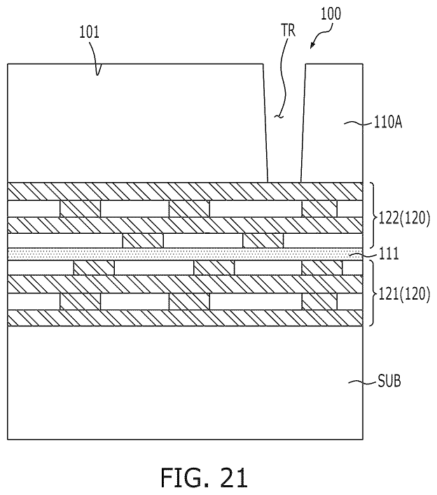

Referring to FIG. 21, a trench TR may be formed in the first semiconductor chip 100.

The trench TR may be formed to create a through-electrode or a through heat-dissipating layer. The trench TR may be formed to penetrate the support substrate 110A. The trench TR may be formed by an etching process. For example, the trench TR may be formed by a wet etching or dry etching process. Part of the support substrate 110A may be removed by the etching process.

The trench TR may be formed so as to reach the upper surface of the back wiring layer 122. Through the trench TR, part of the back wiring layer 122 may be exposed. In some embodiments, the trench TR may be formed so as to penetrate at least one of the plurality of wiring patterns forming the back wiring layer 122. In another embodiment, the trench TR may be formed so as to penetrate part of the first device layer 111 and the front wiring layer 121.

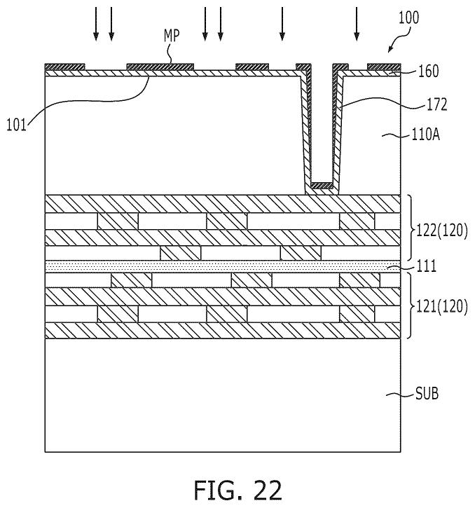

Referring to FIG. 22, the surface heat-dissipating layer 160 may be formed on the first surface 101 of the first semiconductor chip 100, and the through heat-dissipating layer 172 may be formed inside the trench TR.

Subsequently, the mask pattern MP may be disposed on the surface heat-dissipating layer 160 and the through heat-dissipating layer 172. Part of the surface heat-dissipating layer 160 may be covered by the mask pattern MP, and the through heat-dissipating layer 172 may be covered entirely.

The portion exposed by the mask pattern MP may be oxidized or removed, and an insulating material may be formed.

Although the present disclosure has been described above with reference to limited embodiments and drawings, the present disclosure is not limited thereto, and various modifications and changes may be made by those of ordinary skill in the art to which the present disclosure pertains without departing from the inventive concepts of the present disclosure and the scope of equivalents of the claims to be described below.

What is claimed is:

1. A chip stack structure comprising:
a first semiconductor chip comprising a first device layer, a first wiring structure electrically connected to the first device layer, and a through-electrode electrically connected to the first wiring structure;
a second semiconductor chip stacked in a first direction perpendicular to a first surface of the first semiconductor chip, the second semiconductor chip facing the first surface of the first semiconductor chip; and
a surface heat-dissipating layer on the first surface of the first semiconductor chip,
wherein the through-electrode extends through the first surface of the first semiconductor chip in the first direction and overlaps the surface heat-dissipating layer in a second direction perpendicular to the first direction.

2. The chip stack structure according to claim 1, further comprising:
a through heat-dissipating layer extending along a side surface of the through-electrode.

3. The chip stack structure according to claim 2, wherein the through heat-dissipating layer comprises a bent portion extending along the first surface of the first semiconductor chip from the side surface of the through-electrode, and an upper surface of the bent portion is coplanar with an upper surface of the through-electrode.

4. The chip stack structure according to claim 1, further comprising:
a first insulating layer on the first surface and extending around the through-electrode, wherein the through-electrode and the surface heat-dissipating layer are spaced apart in the second direction.

5. The chip stack structure according to claim 1, further comprising:
a first connection terminal on the through-electrode and electrically connecting the first semiconductor chip and the second semiconductor chip;
a second insulating layer on the first surface and having at least one surface that is coplanar with a surface of the surface heat-dissipating layer;
a pad on the second insulating layer, wherein the second insulating layer extends around the pad in plan view; and
a second connection terminal on the pad and electrically connecting the first semiconductor chip and the second semiconductor chip.

6. The chip stack structure according to claim 5, wherein the pad is disposed on an upper surface of the second insulating layer.

7. The chip stack structure according to claim 1, wherein the first wiring structure comprises a first wiring layer between the first device layer and a second surface of the first semiconductor chip,
wherein the through-electrode is connected to the first wiring layer.

8. The chip stack structure according to claim 7, wherein the first wiring structure further comprises a second wiring layer between the first device layer and the first surface of the first semiconductor chip,
wherein the through-electrode is connected to the second wiring layer.

9. The chip stack structure according to claim 1, wherein the second semiconductor chip comprises a second device layer and a second wiring structure electrically connected to the second device layer, and
the second wiring structure comprises a first wiring layer between the second device layer and a first surface of the second semiconductor chip.

10. The chip stack structure according to claim 9, wherein the second semiconductor chip further comprises a second wiring layer electrically connected to the second device layer and between the second device layer and a second surface of the second semiconductor chip.

11. The chip stack structure according to claim 1, wherein the surface heat-dissipating layer comprises graphene.

12. A chip stack structure comprising:
a first semiconductor chip comprising a first device layer, a first wiring structure electrically connected to the first device layer, and a through-electrode electrically connected to the first wiring structure;
a backside pad on a back surface of the first semiconductor chip;
a second semiconductor chip comprising a second device layer and a second wiring structure electrically connected to the second device layer, the second semiconductor chip stacked in a first direction to face the back surface of the first semiconductor chip;
a first connection terminal on the through-electrode and electrically connecting the first semiconductor chip and the second semiconductor chip;
a second connection terminal on the backside pad and electrically connecting the first semiconductor chip and the second semiconductor chip; and
a backside heat-dissipating layer on the back surface of the first semiconductor chip,
wherein the through-electrode extends through the back surface of the first semiconductor chip in the first direction and overlaps the backside heat-dissipating layer in a second direction perpendicular to the first direction.

13. The chip stack structure according to claim 12, further comprising:
a first backside insulating layer on the back surface and extending around the through-electrode; and
a second backside insulating layer on the back surface and extending around the backside pad,
wherein the first backside insulating layer and the second backside insulating layer respectively comprise at least one surface that is coplanar with a surface of the backside heat-dissipating layer.

14. The chip stack structure according to claim 13, further comprising:
a through heat-dissipating layer extending along a side surface and a bottom surface of the through-electrode.

15. The chip stack structure according to claim 14, further comprising:
a substrate between the first device layer and the back surface of the first semiconductor chip,
wherein each of the through-electrode and the through heat-dissipating layer extend through the substrate and the first device layer, and contacts the first wiring structure.

16. The chip stack structure according to claim 14, wherein the through heat-dissipating layer comprises a first portion extending along the side surface of the through-electrode and a second portion extending along the back surface of the first semiconductor chip,
wherein an inner circumferential surface of the second portion contacts the through-electrode, and
wherein an outer circumferential surface of the second portion contacts the first backside insulating layer.

17. The chip stack structure according to claim 13, wherein the backside heat-dissipating layer comprises a conductive material, and
wherein the first backside insulating layer and the second backside insulating layer comprise an oxide of the conductive material.

18. The chip stack structure according to claim 13, wherein the first backside insulating layer and the second backside insulating layer comprise an insulating material.

19. A semiconductor package comprising:
a package substrate; and
a chip stack structure on the package substrate,
wherein the chip stack structure comprises:
a first semiconductor chip mounted on the package substrate, the first semiconductor chip comprising a first device layer, a first wiring structure electrically connected to the first device layer, and a through-electrode electrically connected to the first wiring structure;
a second semiconductor chip comprising a second device layer and a second wiring structure electrically connected to the second device layer, the second semiconductor chip being stacked in a first direction on a back surface of the first semiconductor chip;
a first connection terminal on the through-electrode between the first semiconductor chip and the second semiconductor chip and electrically connecting the first semiconductor chip and the second semiconductor chip;
a first backside insulating layer extending around the through-electrode on the back surface of the first semiconductor chip; and
a backside heat-dissipating layer on the back surface of the first semiconductor chip, the backside heat-dissipating layer comprising at least one surface that is coplanar with a surface of the first backside insulating layer,
wherein the through-electrode extends through the back surface of the first semiconductor chip in the first direction and overlaps each of the first backside insulating layer and the backside heat-dissipating layer in a second direction perpendicular to the first direction.

20. The semiconductor package according to claim 19, further comprising:
a backside pad on the back surface of the first semiconductor chip;
a second connection terminal on the backside pad and electrically connecting the first semiconductor chip and the second semiconductor chip; and
a second backside insulating layer extending around the backside pad on the back surface of the first semiconductor chip.
